(19) United States
(12) Patent Application Publication
(10) Pub. No.: US 2015/0134712 A1
(43) Pub. Date: May 14, 2015

(54) SIGNAL PROCESSING DEVICE, SIGNAL PROCESSING METHOD, AND PROGRAM

(71) Applicant: TOKYO INSTITUTE OF TECHNOLOGY, Tokyo (JP)

(72) Inventors: Isao Yamada, Tokyo (JP); Daichi Kitahara, Tokyo (JP)

(21) Appl. No.: 14/395,087

(22) PCT Filed: Feb. 22, 2013
(86) PCT No.: PCT/JP2013/054596

§ 371 Date: Oct. 17, 2014

(30) Foreign Application Priority Data
Apr. 19, 2012 (JP) 2012-095589

(51) Int. Cl. G01S 13/90; G01R 33/565

(52) U.S. Cl. CPC G01S 13/90; G01R 33/56545
USPC 708/200

(57) ABSTRACT

To improve the stability of numerical calculation for finding a continuous phase of a pair of signal sequences, provided is a signal processing device (10) wherein a spline calculation unit (13) approximates a pair of signal sequences acquired by a signal acquisition unit (11) by spline functions, and an unwrapping processing unit (18) performs phase unwrapping using polynomials. The phase unwrapping is performed according to a procedure where a polynomial-sequence calculation unit (15) calculates a polynomial sequence by applying a Euclidean algorithm to the polynomials of the spline functions, a sign counting unit (17) checks the number of changes of the sign of a numerical sequence formed by arranging the values of the polynomial sequence in each subinterval where the phase is found, and an unwrapping processing unit (18) determines an indefinite portion that is an integral multiple of π on the basis of the number of changes.

### TECHNICAL FIELD

The present invention relates to signal processing that determines a phase of a pair of signal sequences.

### BACKGROUND ART

Signal processing such as remote sensing or magnetic resonance imaging (MRI) needs phase information, and it is important to accurately obtain phase information. In such signal processing, it is necessary to obtain a phase (interference signal and the like) between two signals as a continuous value, and this problem is referred to as “phase unwrapping problem”.

Patent Literature 1 describes a phase compensating circuit that compensates change in a phase of a reflected wave due to movement of a mobile target in order to transmit a radio wave to the target and receive the reflected wave from the target to obtain an image of the target, the phase compensating circuit including: a range bin determining unit for extracting a data sequence of a specific range bin from a received signal sequence of the reflected wave; a phase unwrapping unit for calculating time change in a phase from the extracted data sequence, and removing turnback of the phase included in the calculated time change in the phase; a phase compensation amount calculating unit for performing fitting using a least square method on data representing the time change in the phase from which the turnback of the phase has been removed, detecting a second or higher change component of the time change in the phase, and calculating, from the detected result, a phase compensation amount that reduces the second or higher change component; and a phase compensating unit for compensating the received signal sequence of the reflected wave in accordance with the obtained phase compensation amount.

Patent Literature 2 describes a three-dimensional temperature measuring method using an MRI device, in which a three-dimensional MR photographing sequence including three-dimensional temperature distribution information is performed, a three-dimensional phase distribution is calculated from the obtained three-dimensional complex MR image, a three-dimensional phase unwrapping process is then performed, from the three-dimensional phase distribution after the unwrapping process, a three dimensional temperature distribution is calculated, and a volume rendering process is performed on this calculated result to create and display a three-dimensional temperature image.

Patent Literature 3 describes a method for cancelling a narrow band interference signal in a receiver, the method including the steps of: subtracting a reference signal from a received input signal; calculating a phase of the subtracted result on the basis of an arctangent function; removing modulo 2π limitation produced by the arctangent function, thereby performing an unwrapping function on an output signal from the arctangent function, and thereby generating absolute value phase representation; comparing phase representing values shifted by predetermined time, and thereby determining a frequency offset; and canceling a narrow band interference object on the basis of the result of the determined frequency offset.

Non-patent Literatures 1 to 3 describe an algebraic solution in which regarding two real polynomial functions B₍₀₎(r), B₍₁₎(r), a phase θ(r)=tan⁻¹(B₍₁₎(r)/B₍₀₎(r)) that is a continuous function is obtained by a calculating method that is extended Euclidean algorithm.

### PRIOR ART DOCUMENT

### Patent Document

Patent Literature 1: Japanese Patent No. 3395606

Patent Literature 2: Japanese Unexamined Patent Publication No. 2000-300536

Patent Literature 3: Japanese Unexamined Patent Publication No. 2007-521729

### Non-patent Document

Non-patent Literature 1: I. Yamada, K. Kurosawa, H. Hasegawa, K. Sakaniwa, “Algebraic Multidimensional Phase Unwrapping and Zero Distribution of Complex Polynomials—Characterization of Multivariate Stable Polynomials”, IEEE Transactions on Signal Processing, 1998, vol. 46, no. 6, p. 1639-1664
Non-patent Literature 2: I. Yamada, N. K. Bose, “Algebraic Phase Unwrapping and Zero Distribution of Polynomial for Continuous-Time Systems”, IEEE Transactions on Circuits and Systems I: Fundamental Theory and Applications, 2002, vol. 49, no. 3, p. 298-304
Non-patent Literature 3: I. Yamada, K. Oguchi, “High-Resolution Estimation of the Directions-of-Arrival Distribution by Algebraic Phase Unwrapping Algorithms”, Multidimensional Systems and Signal Processing, Springer, 2011, vol. 22, no. 1-3, p. 191-211

### SUMMARY OF INVENTION

### Technical Problem

In actual signal processing, signals are not necessarily expressed by real polynomial functions, and thus, even if the signals are approximated by polynomials, the more the order of polynomials increases, the more instable numerical calculation becomes. For this reason, it is difficult to apply the algebraic solution of Non-patent Literatures 1 to 3 to actual signal processing to obtain a continuous phase. An object of the present invention is to improve the stability of numerical calculation for finding a continuous phase of a pair of signal sequences.

### Solution to Problem

In order to attain the above object, the present invention provides a signal processing device including: a signal acquisition unit that acquires a pair of signal sequences; a first calculating unit that calculates a first function and a second function that are piecewise polynomials respectively approximating, by polynomials for each of a plurality of subintervals, the pair of signal sequences acquired by the signal acquisition unit; a second calculating unit that calculates a numerical sequence of values obtained by substituting one point in each of the plurality of subintervals into a polynomial remainder sequence obtained by applying a Euclidean algorithm to the first function and the second function calculated by the first calculating unit; a phase determining unit that determines a phase of the pair of signal sequences at the one point, on the basis of a sign of each term of the numerical sequence calculated by the second calculating unit; and a signal outputting unit that outputs a signal sequence of phases determined by the phase determining unit for each of the plurality of subintervals.

The phase determining unit may determine, on the basis of the number of changes in signs of values of the numerical sequence between neighboring two terms in the numerical sequence, a value of an indefinite portion of an integral multiple of it that is involved in the phase of the pair of signal sequences at the one point.

The first calculating unit may calculate, for each of the pair of signal sequences, a piecewise polynomial such that the piecewise polynomial passes through each sample point of the signal sequence concerned, and that polynomials thereof in subintervals neighboring each other are smoothly continued.

The second calculating unit may calculate, instead of the numerical sequence obtained from the polynomial remainder sequence, a numerical sequence obtained by multiplying, by a positive constant value, respective terms of the numerical sequence concerned, in each of the plurality of subintervals, on the basis of determinants of a plurality of subresultant matrices that are minor matrices of a resultant matrix concerning the first function and the second function.

The signal outputting unit may output the signal sequence of phases at points for which the phase determining unit has determined the phases, and the points include neighboring two points at which phase difference is larger than π.

Additionally, the present invention provides a signal processing method including the steps of: acquiring a pair of signal sequences; calculating a first function and a second function that are piecewise polynomials respectively approximating, by polynomials for each of a plurality of subintervals, the acquired pair of signal sequences; calculating a numerical sequence of values obtained by substituting one point in each of the plurality of subintervals into a polynomial remainder sequence obtained by applying a Euclidean algorithm to the calculated first and second functions; determining a phase of the pair of signal sequences at the one point, on the basis of a sign of each term of the calculated numerical sequence; and outputting a signal sequence of phases determined for each of the plurality of subintervals.

Additionally, the present invention provides a program causing a computer to execute a process, the process including: acquiring a pair of signal sequences; calculating a first function and a second function that are piecewise polynomials respectively approximating, by polynomials for each of a plurality of subintervals, the acquired pair of signal sequences; calculating a numerical sequence of values obtained by substituting one point in each of the plurality of subintervals into a polynomial remainder sequence obtained by applying a Euclidean algorithm to the calculated first and second functions; determining a phase of the pair of signal sequences at the one point, on the basis of a sign of each term of the calculated numerical sequence; and outputting a signal sequence of phases determined for each of the plurality of subintervals.

### Advantageous Effects of Invention

According to the present invention, it is possible to improve the stability of numerical calculation for finding a continuous phase of a pair of signal sequences, as compared with the case of not employing the present invention.

### BRIEF DESCRIPTION OF DRAWINGS

FIG. 1 is a diagram for describing a principle of a method for measuring an altitude of the earth's surface by an interferometric synthetic aperture radar;

FIGS. 2A to 2C are images representing examples of phase data on which phase unwrapping is performed;

FIG. 3 is a block diagram illustrating a functional configuration example of a signal processing device according to the embodiment;

FIG. 4 is a flowchart illustrating outline of an operation example of the signal processing device according to the embodiment;

FIG. 5 is a flowchart illustrating an operation example of the spline calculation unit in the signal processing device according to the embodiment;

FIG. 6 is a flowchart illustrating an operation example of the polynomial-sequence calculating unit in the signal processing device according to the first embodiment;

FIG. 7 is a flowchart illustrating an operation example of the polynomial-sequence calculating unit in the signal processing device according to the second embodiment;

FIGS. 8A to 8C are graphs of the one input signal used in the numerical simulation of phase unwrapping;

FIGS. 9A to 9C are graphs of the other input signal used in the numerical simulation of phase unwrapping;

FIGS. 10A to 10C are graphs of a wrapped phase of the input signals of FIGS. 8A to 8C and FIGS. 9A to 9C;

FIGS. 11A to 11C are graphs of an unwrapped phase of the input signals of FIGS. 8A to 8C and FIGS. 9A to 9C;

FIGS. 12A to 12C are graphs representing results of the numerical simulation in which phase unwrapping is performed on the input signals of FIGS. 8A to 8C and FIGS. 9A to 9C; and

FIG. 13 illustrates a hardware configuration of a computer capable of implementing the embodiment.

### DESCRIPTION OF EMBODIMENTS

In the following, an embodiment of the present invention is described with reference to the accompanying drawings.

A signal processing device according to the present embodiment calculates a phase Θ=tan⁻¹(G/F) from a pair of acquired signal sequences F and G, and outputs the phase Θ. This phase Θ has indefiniteness of mπ (m is an integer) and is not uniquely obtained. Determining appropriate integer values m that make Θ continuous is referred to as “phase unwrapping”. The signal processing device according to the present embodiment performs this phase unwrapping.

First, an example of a system to which the signal processing device according to the present embodiment is applied will be described.

There is a system that measures information on the earth's surface by using a synthetic aperture radar (SAR). The SAR is a radar in which a radio wave is emitted toward the ground from the radar mounted on an airplane or a satellite, the radio wave reflected by the target object is received by its own antenna, and the antenna itself is moved by the airplane or the satellite to accomplish a virtually large aperture face. An interferometric synthetic aperture radar (interferometric SAR) that is one of synthetic aperture radars measures an altitude of the earth's surface or change in an altitude of the earth's surface caused by crustal movement, from interference fringes generated by making two sets of complex images obtained for the same area interfere with each other.

Assume that the two sets of complex images are A₁=A₀exp(iφ₁) and A₂=A₀exp(iφ₂), then the interference fringes are A₁A₂*=|A₀|²exp(iΔφ). In this case, Δφ=φ₁−φ₂ is a phase difference, and is expressed by the following formula. The description of “real” means a real part, “imag” means an imaginary part, and “*” means a complex conjugate.

$$Δφ = {tan}^{- 1} ( \frac{imag ( {A}_{1} {A}_{2}^{*} )}{real ( {A}_{1} {A}_{2}^{*} )} ) + m π \\ ( m IS INTEGER ) \qquad [ Formula 1 ]$$

Although Δφ needs to be obtained for obtaining an altitude of the earth's surface, the value of Δφ is not uniquely determined since a tangent function (tan) has periodicity of a period π. For this reason, the signal processing device according to the present embodiment performs phase unwrapping to determine an appropriate integer m that makes a phase Δφ continuous.

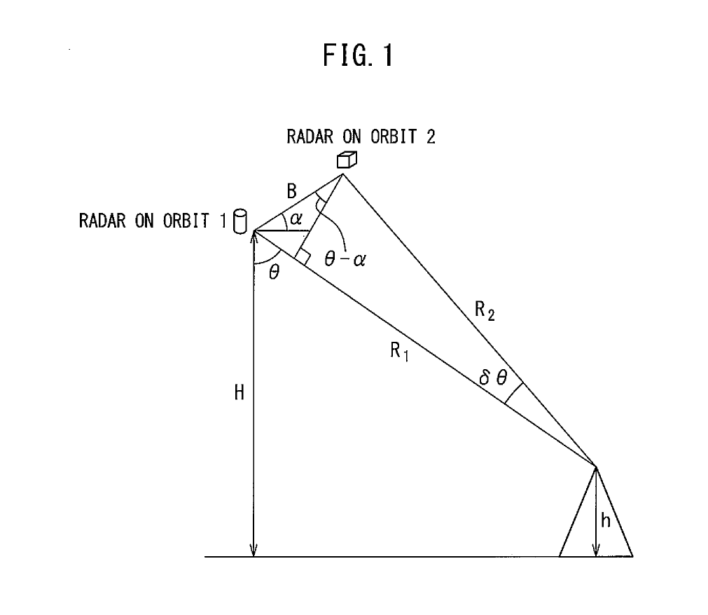

When a continuous phase Δφ is obtained by phase unwrapping, an altitude of the earth's surface is obtained as follows, for example. FIG. 1 is a diagram for describing a principle of a method for measuring an altitude of the earth's surface by an interferometric SAR. R₁ and R₂ are distances from radars on respective orbits 1 and 2 to a target object on the earth's surface, B is a distance between the radars on the orbits 1 and 2, H is an altitude of the radars, h is an altitude of the measuring target, and angles θ, α, and δθ are determined as in FIG. 1. Unknowns are R₁, R₂, h, and θ. Then, R₁ is R₁=B sin (θ−α)+R₂ cos δθ. In fact, δθ is δθ≈0, so that cos δθ is cos δθ≈1, and R₁ is R₁=B sin(θ−α)+R₂. Then, ΔR that is a difference between R₁ and R₂ is ΔR=R₁−R₂=B sin(θ−α). Accordingly, the phase difference Δφ is expressed by the following formula.

$$Δφ = \frac{4 π B sin ( θ - α )}{λ} \qquad [ Formula 2 ]$$

λ is a wavelength of the radio wave. Since h is h=H−R₁ cos θ, θ is obtained from Δφ, and further, h is obtained so that the altitude h of the earth's surface is measured.

As another example of a system to which the signal processing device according to the present embodiment is applied, there is a nuclear magnetic resonance image system using MRI. MRI is a technique of generating an image of a density and a state of protons (nucleuses of hydrogen atoms) in a body. Since approximately 90% of a human body is structured by water and a fat, and each of them includes many hydrogen atoms, a rough structure of the body can be found from a density and a state of protons. A gradient field echo (GRE) method is one MRI imaging method, and uses a technique referred to a Dixon method in which from a mixture of a signal of water and a signal of a fat, components of both of the water and the fat are separated and images are formed.

The Dixon method uses a phenomenon (chemical shift phenomenon) in which shift is generated in a nuclear magnetic resonance spectrum by a difference in a molecular structure between water and a fat. Appropriately applying a pulse from an outside obtains a signal in which signals of water and a fat have the same phase, and a signal in which signals of water and a fat have the opposite phases, as in the following formulae.

Same Phase (in-Phase) s₀=(W+F)exp(iθ₀)

Opposite phases (out-phase) s₁=(W−F)exp(i(θ₀+φ)

In these formulae, W, F, and θ₀ are constants. Then, since s₀*s₁/s₀s₁*=exp(i2φ), a phase difference φ is obtained as follows.

$$\begin{matrix}2 ϕ = {tan}^{- 1} ( \frac{imag ( \frac{{s}_{0}^{*} {s}_{1}}{{s}_{0} {s}_{1}^{*}} )}{real ( \frac{{s}_{0}^{*} {s}_{1}}{{s}_{0} {s}_{1}^{*}} )} ) + m π & ( m IS INTEGER )\end{matrix} \qquad [ Formula 3 ]$$

The signal processing device according to the present embodiment is used in order to determine an appropriate integer m in this case to obtain a continuous phase 2φ. When the continuous phase 2φ is obtained, a water image and a fat image are obtained by the following formulae.

$$\begin{matrix}WATER IMAGE & \vert W exp ( {iθ}_{0} ) \vert = \frac{\vert {s}_{0} + {s}_{1} exp ( - iϕ ) \vert}{2} \\ FAT IMAGE & \vert F exp ( {iθ}_{0} ) \vert = \frac{\vert {s}_{0} - {s}_{1} exp ( - iϕ ) \vert}{2}\end{matrix} \qquad [ Formula 4 ]$$

Thus, in signal processing and image processing, a pair of real-valued continuous functions f(x) and g(x) is given, and it is required to determine a continuous function Θ(x) that satisfies tan Θ(x)=g(x)/f(x). Generally, the number of independent variables is not necessarily one, and application in a case of two variables is particularly important. However, phase unwrapping of two variables can be accomplished by calculating phase unwrapping of one variable for each variable, as well. For this reason, in the present embodiment, for simplification, functions of one real variable x are considered.

Generally, when a pair of real values (x, y) (x is not 0) is given, a real value θ that satisfies tan θ=y/x is called a phase made by (x, y). However, as described above, a tangent function tan is a periodic function of a period π, so that this θ is not uniquely determined. In other words, a phase made by (x, y) may be any one of θ=θ₀+mπ (m is an arbitrary integer) using the unique θ₀ε(−π/2,π/2) (referred to as principal value) that satisfies tan θ₀=y/x.

The phase unwrapping problem for determining the above-mentioned continuous function Θ(x) is a problem for creating a continuous function Θ by performing correction of adding an appropriate integral multiple of π to the principal value at x where f(x) is not 0, and allocating an appropriate real value to Θ(x) at x where f(x) is 0. Methods of conventional phase unwrapping are trial-and-error manner, and a method of accomplishing systematic and stable phase unwrapping has not been established. Since performance of many state-of-the-art measuring systems largely depends on whether phase unwrapping succeeds or not, a large spreading effect can be expected when a technique of accomplishing stable phase unwrapping is established.

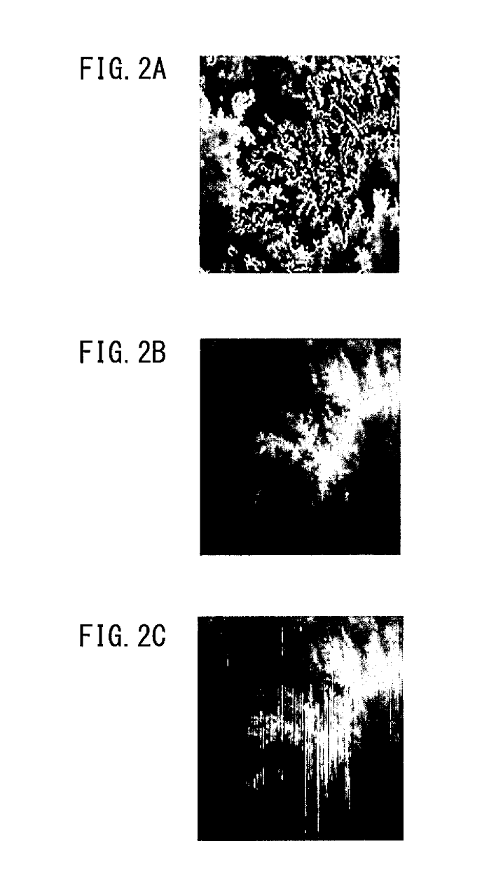

FIGS. 2A to 2C are images representing examples of phase data on which phase unwrapping is performed. These images are cited from Web page [online] [search on Apr. 2, 2012] (URL:http://cis.k.hosei.ac.jp/research/laboratory/digital/hanaizumi/remote_sensing.html) of the laboratory of Hiroshi Hanaizumi at information science department of Hosei University.

FIG. 2A is an image of two-dimensional phase data before phase unwrapping is performed. In the respective images of FIGS. 2A to 2C, shading of black and white indicates magnitude of a value of a phase. In FIG. 2A, a phase is limited to a range between −π and +π. For this reason, a point where a value discontinuously changes from −π to +π or from +π to −π exists, so that a part where change in shading is discontinuous and black and white is clearly separated from each other can be seen. A phase of which a value (range) is thus limited to a range between −π and +π or the like is referred to as “wrapped phase” in the following.

FIG. 2B is an image obtained by appropriately performing phase unwrapping on the phase data of FIG. 2A. In the case of FIG. 2B, a value of a phase is not limited to the range between −π and +π, and a point where a value discontinuously changes does not exist. Due to continuous change in the phase at all points, it can be seen that shading continuously changes. A phase of which range limitation is thus removed by performing phase unwrapping is referred to as “unwrapped phase” in the following.

Meanwhile, FIG. 2C is an image when phase unwrapping of the phase data of FIG. 2A fails. In other words, in FIG. 2C, a point where a phase discontinuously changes by 2π exists even after phase unwrapping is performed, so that a part where shading discontinuously changes can be seen. In conventional trial-and-error phase unwrapping methods, base assumption is that fluctuation in an unwrapped phase between neighboring sample points does not exceed ±π, so that phase unwrapping fails as in FIG. 2C when a point where a phase drastically changes exists, for example.

The signal processing device according to the present embodiment obtains, by a systematic method, a continuous unwrapped phase for a pair of signal sequences that are not necessarily expressed by a real polynomial function. For this purpose, the signal processing device according to the present embodiment approximates the acquired pair of signal sequences by spline functions, respectively, and performs phase unwrapping by using polynomials of respective subintervals of the obtained spline functions. The phase unwrapping is performed by a procedure of applying a Euclidean algorithm to the polynomials of the spline functions to calculate a polynomial sequence, finding the number of changes in signs of a numerical sequence made by arranging values of the polynomial sequence at a point in each subinterval at which a phase is obtained, and determining an indefinite portion of an integral multiple of it on the basis of the number of changes.

In the present embodiment, the term “continuous” is used as mathematical meaning for functions, and is used as meaning that there is no unnatural “jump” of change in a value as seen in FIGS. 2A and 2C, for a phase of a discrete signal treated by an actual system.

### First Embodiment

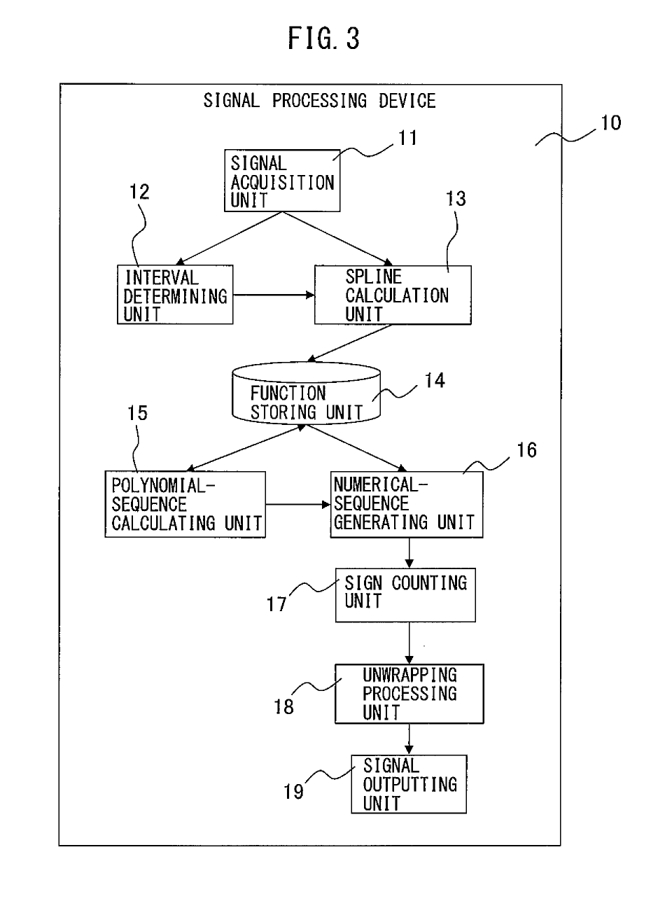

FIG. 3 is a block diagram illustrating a functional configuration example of a signal processing device 10 according to the present embodiment. As illustrated in the drawing, the signal processing device 10 includes a signal acquisition unit 11, an interval determining unit 12, a spline calculation unit 13, a function storing unit 14, a polynomial-sequence calculating unit 15, a numerical-sequence generating unit 16, a sign counting unit 17, an unwrapping processing unit 18, and a signal outputting unit 19.

The signal acquisition unit 11 acquires a pair of processing-target signal sequences. For example, in a case of the above-described interferometric SAR, a real part and an imaginary part of A₁A₂* are acquired as a pair of signal sequences, respectively, and in a case of MRI, a real part and an imaginary part of s₀*s₁/s₀s₁* are acquired as a pair of signal sequences, respectively. In the following, a pair of signal sequences acquired by the signal acquisition unit 11 are respectively represented by F(x) and G(x). For example, when these signal sequences are time series signals, x represents time.

The interval determining unit 12 determines subintervals that are used when the spline calculation unit 13 obtains spline functions from signal sequences acquired by the signal acquisition unit 11. When the signal acquisition unit 11 acquires signals F(x) and G(x) at sample points x₀, x₁, . . . , x_{N}, the interval determining unit 12 determines, as [x₀, x₁], . . . , [x_{N-1}, x_{N}] for example, subintervals that are used when the spline calculation unit 13 obtains spline functions. The expression of interval [a, b] means an interval including end points a and b.

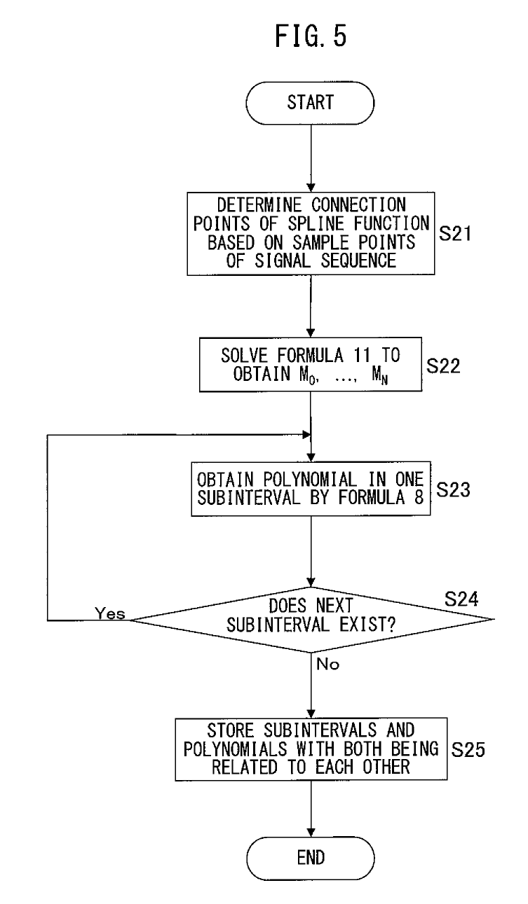

The spline calculation unit 13 calculates spline functions S_{F}(x) and S_{G}(x) as one example of piecewise polynomials that approximate the signal sequences F(x) and G(x), respectively that are acquired by the signal acquisition unit 11. Details of a process in which the spline calculation unit 13 obtains the spline functions S_{F}(x) and S_{G}(x) are described later by using FIG. 5. In the present embodiment, the spline calculation unit 13 is provided as one example of a first calculating unit.

The function storing unit 14 stores the spline functions S_{F}(x) and S_{G}(x) calculated by the spline calculation unit 13, and a polynomial sequence calculated by the polynomial-sequence calculating unit 15.

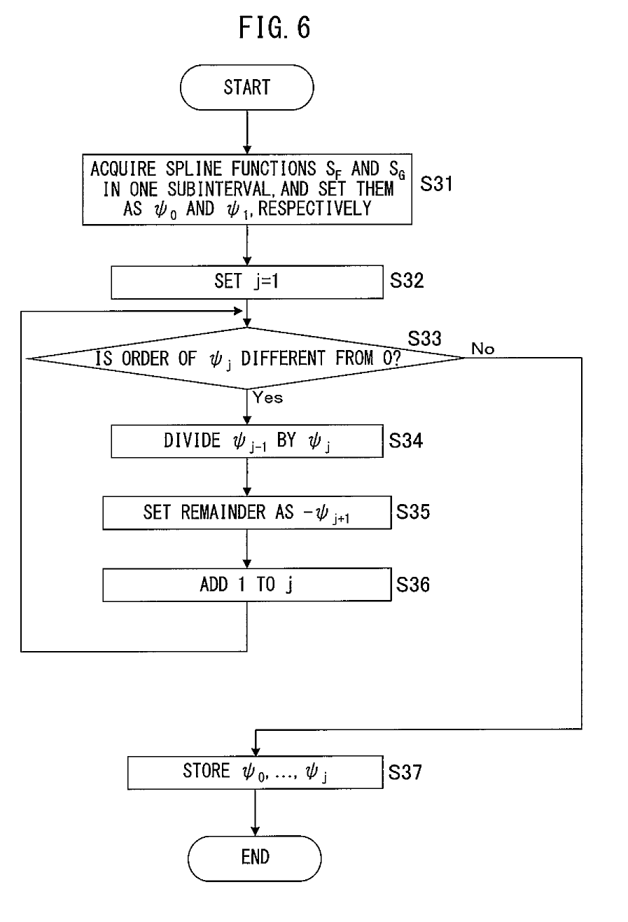

For each of the subintervals [x₀, x₁], . . . , [x_{N-1}, x_{N}] in which the respective spline functions S_{F}(x) and S_{G}(x) calculated by the spline calculation unit 13 are expressed by polynomials, the polynomial-sequence calculating unit 15 applies a Euclidean algorithm to S_{F}(x) and S_{G}(x) in the subinterval concerned to calculate a polynomial sequence. A process in which the polynomial-sequence calculating unit 15 obtains the polynomial sequence is performed in accordance with the procedure specified in Non-patent Literature 3. The details are described later by using FIG. 6.

The numerical-sequence generating unit 16 generates a numerical sequence obtained by arranging values of the polynomial sequence at a point x in each subinterval for which the polynomial-sequence calculating unit 15 has calculated the polynomial sequence. For example, for the subinterval [x₀, x₁], a value of each polynomial at x₀ in the subinterval (i.e., a value when x₀ is substituted) is calculated, and the calculated results are arranged in turn to make a numerical sequence. In the present embodiment, the polynomial-sequence calculating unit 15 and the numerical-sequence generating unit 16 are provided as one example of a second calculating unit.

The sign counting unit 17 counts the number of changes in signs of values of the numerical sequence between neighboring two terms in the numerical sequence generated by the numerical-sequence generating unit 16.

The unwrapping processing unit 18 determines, on the basis of the number of changes in signs obtained by the sign counting unit 17 a value of an indefinite portion of an integral multiple of π that is involved in a phase of the signal sequences F(t) and G(t) at a point x=t for which the numerical-sequence generating unit 16 has generated the numerical sequence. Details of a process in which the unwrapping processing unit 18 determines a value of an integral multiple of π will also be described later. In the present embodiment, the sign counting unit 17 and the unwrapping processing unit 18 are provided as one example of a phase determining unit.

The signal outputting unit 19 outputs, as a signal sequence, values of phases at respective points obtained by the unwrapping processing unit 18. Since phases determined by the unwrapping processing unit 18 of the present embodiment continuously changes at the respective points, the signal sequence of phases output by the signal outputting unit 19 becomes continuous, as well.

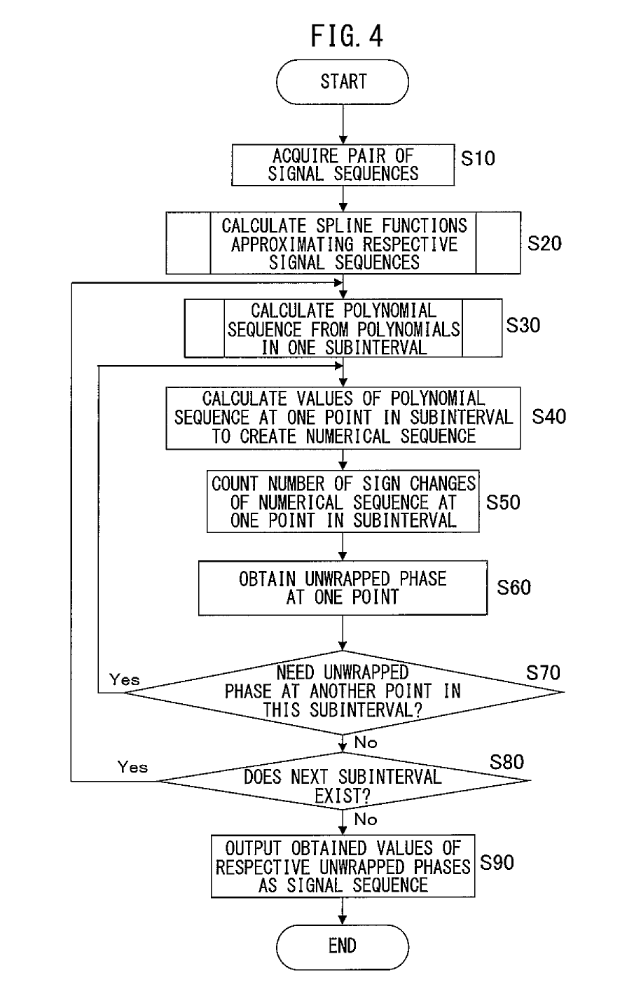

In the following, operation of the signal processing device 10 of the present embodiment is described. FIG. 4 is a flowchart illustrating outline of an operation example of the signal processing device 10.

First, the signal acquisition unit 11 acquires a pair of signal sequences F(x) and G(x) at sample points x₀, x₁, . . . , x_{N} (step 10). Then, the interval determining unit 12 determines subintervals [x₀, x₁], . . . , [x_{N-1}, x_{N}] of x, and on that basis, the spline calculation unit 13 calculates spline functions S_{F}(x) and S_{G}(x) that approximate the respective signal sequences (step 20). The function storing unit 14 stores the calculated spline functions S_{F}(x) and S_{G}(x).

Then, for the first subinterval [x₀, x₁] of x, the polynomial-sequence calculating unit 15 calculates a polynomial sequence from the spline functions S_{F}(x) and S_{G}(x) stored in the function storing unit 14 (step 30). When S_{F}(x) and S_{G}(x) are respectively expressed by polynomials f₀(x) and g₀(x) in the subinterval [x₀, x₁], the polynomial-sequence calculating unit 15 applies a Euclidean algorithm to the f₀(x) and g₀(x) to calculate a polynomial sequence {ψ₀(x), . . . , ψ_{q}(x)}. In this case, q is the number at which ψ_{q}(x) becomes the zeroth order (a constant). For example, when ψ₀(x) and ψ₁(x) are the third order, this polynomial sequence is a finite numerical sequence of which order is reduced step by step such that ψ₂(x) is the second order, ψ₃(x) is the first order, and ψ₄(x) is the zeroth order (a constant) (in this example, q is 4). In the present embodiment, this polynomial sequence is also referred to as “polynomial remainder sequence”. The function storing unit 14 stores the calculated polynomial sequence {ψ₀(x), . . . , ψ_{q}(x)}.

Next, for the point x=t in the subinterval [x₀, x₁], the numerical-sequence generating unit 16 calculates values of the polynomial sequence {ψ₀(x), . . . , ψ_{q}(x)}, and arranges the values to create a numerical sequence {ψ₀(t), . . . , ψ_{q}(t)} (step 40). Then, for the numerical sequence {ψ₀(t), . . . , ψ_{q}(t)}, the sign counting unit 17 counts the number of changes in signs between neighboring two terms (step 50). The number of sign changes is written as V{ψ(t)}.

A method for obtaining the number V{ψ(t)} of sign changes is concretely described. For example, it is assumed that the number of terms of the numerical sequence is six, and signs of the respective terms are {+, +, −, 0, 0, +}. Although the sign does not change and maintains a positive from the first term to the second term, the sign changes from a positive to a negative from the second term to the third term, so that this is counted as a one time. The fourth term and the fifth term are zero, such zero terms are skipped, and next, the sixth term which is not zero is checked. From the third term to the sixth term, the sign changes from a negative to a positive, so that this is counted as a one time. Accordingly, for this numerical sequence, V{ψ(t)} is V{ψ(t)}=2.

According to Non-patent Literatures 1 to 3, it has been proved that an unwrapped phase θ(t) of the polynomials f(x) and g(x) at x=t is given by the following formula.

$$θ ( t ) = θ ( {t}_{0} ) - {tan}^{- 1} ( \frac{g ( {t}_{0} )}{f ( {t}_{0} )} ) + {tan}^{- 1} ( \frac{g ( t )}{f ( t )} ) + ( V \{ ψ ( t ) \} - V \{ ψ ( {t}_{0} ) \} ) π \qquad [ Formula 5 ]$$

In this formula, t₀ is a reference point for obtaining the unwrapped phase θ(t). The second term and the third term in the right side are values (principal values) in a range (−π/2, π/2), and V{ψ(t)} is the number of sign changes at x=t obtained at the step 50. V{ψ(t₀)} is the number of sign changes of a numerical sequence in which values of the polynomial sequence {ψ₀(x), . . . , ψ_{q}(x)} at the reference point x=t₀ are arranged. In other words, what multiple of π is added to the principal values to obtain an unwrapped phase can be strictly determined, by the above formula, from the number V{ψ(t)} of sign changes obtained at the step 50.

Since the spline functions S_{F}(x) and S_{G}(x) are expressed by polynomials different for the respective subintervals, in the present embodiment, the above-described reference point t₀ is also determined for each of the subintervals. For example, like “x₀ for the subinterval [x₀, x₁], . . . , x_{N-1} for the subinterval [x_{N-1}, x_{N}]”, the start point (left end point) of each subinterval may be set as the reference point t₀.

Accordingly, the unwrapping processing unit 18 sets, for the subinterval [x₀, x₁], the reference point as t₀=x₀, and calculates the formula 5 by using the polynomials f₀(x) and g₀(x) in the subinterval [x₀, x₁] stored in the function storing unit 14 and V{ψ(t)} obtained at the step 50. In other words, the unwrapping processing unit 18 obtains the unwrapped phase θ(t) at x=t in the subinterval [x₀, x₁] by calculating the following formula (step 60).

$$θ ( t ) = θ ( {x}_{0} ) - {tan}^{- 1} ( \frac{{g}_{0} ( {x}_{0} )}{{f}_{0} ( {x}_{0} )} ) + {tan}^{- 1} ( \frac{{g}_{0} ( t )}{{f}_{0} ( t )} ) + ( V \{ ψ ( t ) \} - V \{ ψ ( {x}_{0} ) \} ) π \qquad [ Formula 6 ]$$

Then, when an unwrapped phase is obtained also for a different point in the subinterval [x₀, x₁], the process returns to the step 40, and when the process is shifted to a next subinterval [x₁, x₂], the process advances to step 80 (step 70). Although an unwrapped phase may be calculated at any point in each subinterval, in the present embodiment, an unwrapped phase is calculated for at least end points x₀, x₁, . . . , x_{N} in the respective subintervals.

When a next subinterval exists, the process returns to the step 30 (yes at step 80). In obtaining an unwrapped phase in the subinterval [x₁, x₂], the unwrapping processing unit 18 sets the reference point as t₀=x₁, and performs calculation in the same manner as in the formula 6 by using the polynomials f₁(x) and g₁(x) in the subinterval [x₁, x₂] and V{ψ(t)} obtained at the step 50. The same applies to the subinterval [x₂, x₃] and the subsequent subintervals.

When a next subinterval does not exist, i.e., when unwrapped phases are obtained up to the subinterval [x_{N-1}, x_{N}], the process advances to step 90 (no at step 80). Then, the signal outputting unit 19 outputs, as a signal sequence, the values of the respective unwrapped phases obtained up until now (step 90). With that, the operation of the signal processing device 10 is finished.

Next, the process in which the spline calculation unit 13 calculates the spline functions S_{F}(x) and S_{G}(x) at the step 20 in FIG. 4 will be described.

In the present embodiment, by using sample values of the signal sequences F(x) and G(x), the spline calculation unit 13 approximates each of F(x) and G(x) by spline functions to obtain two piecewise polynomials that pass through the respective sample points. A spline function S(x) of the n-th order is defined as “S(x) is a polynomial of the n-th or less order in each subinterval, and S(x) and its derivative of the (n−1)th or less order are continuous functions in an entire domain”. In other words, a spline function is a piecewise polynomial in which a plurality of polynomials are connected to each other, and is a function that is smooth in mathematical meaning even at each connection point (joint) between the polynomials.

Generally, when a finite number of sample points (xₖ, f(xₖ)) (k=1, 2, 3, . . . , p) of a function f(x) are given, to obtain some function h(x) passing through these sample points, h(x) may be set as a polynomial of the (p−1)th order, and simultaneous equations concerning coefficients of the polynomial may be solved. However, when the number p of the sample points becomes large, the polynomial h(x) largely vibrates at x other than the sample points, and for this reason, interpolation by one polynomial may not be appropriate. Meanwhile, using a spline function can make the order lower than the case of interpolation by one polynomial, resulting in a function of which vibration is small. In view thereof, in the present embodiment, an interpolation algorithm of a spline function is used to each of the signal sequences F(x) and G(x).

Next, a calculating method when sample points are interpolated by a spline function of the third order will be described. In this example, sample points are made to be identical to the connection points of the spline function. Namely, when samples (xₖ, yₖ) (k=0, 1, . . . , N, and x₀<x₁< . . . <x_{N}) are given, different cubic functions each make connection between the sample points such that a cubic function is set in the subinterval [x₀, x₁], and a different cubic function is set in the subinterval [x₁, x₂], for example. When the spline function to be obtained is S(x), S(x) passes through all of the sample points (xₖ, yₖ) (k=0, 1, . . . , N), and the second-or-less-order derivatives of S(x) become continuous in (x₀, x_{N}).

When a value of the second-order derivative at the sample point xₖ is represented by Mₖ (k=0, 1, . . . , N), the second-order derivative S″(x) of S(x) in the subinterval [xₖ₋₁, xₖ] (k=1, 2, . . . , N) is expressed by the following formula.

$$\begin{matrix}{S}^{′} ( x ) = \frac{{M}_{k} - {M}_{k - 1}}{{x}_{k} - {x}_{k - 1}} x + \frac{{M}_{k - 1} {x}_{k} - {M}_{k - 1} {x}_{k - 1}}{{x}_{k} - {x}_{k - 1}} \\ = {M}_{k - 1} \frac{{x}_{k} - x}{{h}_{k}} + {M}_{k} \frac{x - {x}_{k - 1}}{{h}_{k}}\end{matrix} \qquad [ Formula 7 ]$$

In this regard, hₖ is hₖ=xₖ−xₖ₋₁. When this is integrated twice, and S(xₖ₋₁)=yₖ₋₁ and S(xₖ)=yₖ are used, S(x) in the subinterval [xₖ₋₁, xₖ] is expressed as in the following formulae.

$$S ( x ) = {M}_{k - 1} \frac{{( {x}_{k} - x )}^{3}}{6 {h}_{k}} + {M}_{k} \frac{{( x - {x}_{k - 1} )}^{3}}{6 {h}_{k}} + ax + b \\ a = \frac{{y}_{k} - {y}_{k - 1}}{{h}_{k}} - \frac{{M}_{k} - {M}_{k - 1}}{6} {h}_{k} \\ AND \\ b = \frac{{x}_{k} {y}_{k - 1} - {x}_{k - 1} {y}_{k}}{{h}_{k}} + \frac{{M}_{k} {x}_{k - 1} - {M}_{k - 1} {x}_{k}}{6} {h}_{k} \qquad [ Formula 8 ]$$

Therefore, when Mₖ (k=0, 1, . . . , N) is known, S(x) can be obtained. In order to obtain this Mₖ, the first-order derivative is considered. Then, from the above result, S′(x) in the subinterval [xₖ₋₁, xₖ] is expressed by the following formula.

$${S}^{′} ( x ) = - {M}_{k - 1} \frac{{( {x}_{k} - x )}^{2}}{2 {h}_{k}} + {M}_{k} \frac{{( x - {x}_{k - 1} )}^{2}}{2 {h}_{k}} + \frac{{y}_{k} - {y}_{k - 1}}{{h}_{k}} - \frac{{M}_{k} - {M}_{k - 1}}{6} {h}_{k} \qquad [ Formula 9 ]$$

Accordingly, a left-side differential coefficient and a right-side differential coefficient of S′(x) at xₖ (k=1, 2, . . . , N−1) are expressed as in the following formulae.

$$\begin{matrix}{S}^{′} ( {x}_{k} - ) = {M}_{k} \frac{{h}_{k}^{2}}{2 {h}_{k}} + \frac{{y}_{k} - {y}_{k - 1}}{{h}_{k}} - \frac{{M}_{k} - {M}_{k - s}}{6} \\ = \frac{{h}_{k}}{6} {M}_{k - 1} + \frac{{h}_{k}}{3} {M}_{k} + \frac{{y}_{k} - {y}_{k - 1}}{{h}_{k}}\end{matrix} \\ \begin{matrix}{S}^{′} ( {x}_{k} + ) = - {M}_{k} \frac{{h}_{k + 1}^{2}}{2 {h}_{k + 1}} + \frac{{y}_{k + 1} - {y}_{k}}{{h}_{k + 1}} - \frac{{M}_{k + 1} - {M}_{k}}{6} {h}_{k - 1} \\ = - \frac{{h}_{k + 1}}{3} {M}_{k} - \frac{{h}_{k + 1}}{6} {M}_{k + 1} + \frac{{y}_{k + 1} - {y}_{k}}{{h}_{k + 1}}\end{matrix} \qquad [ Formula 10 ]$$

By continuity of the first-order derivative, S′(xₖ−)=S′(xₖ+) is established so that the following formula is introduced.

$$\frac{{h}_{k}}{6} {M}_{k - 1} + \frac{{h}_{k} + {h}_{k + 1}}{3} {M}_{k} + \frac{{h}_{k}}{6} {M}_{k + 1} = \frac{{y}_{k + 1} - {y}_{k}}{{h}_{k + 1}} - \frac{{y}_{k} - {y}_{k - 1}}{{h}_{k}} \\ ( k = 1 , 2 , … , N - 1 ) \qquad [ Formula 11 ]$$

While the number of unknowns is (N+1) of Mₖ (k=0, 1, . . . , N), the number of equations of the formula 11 is only (N−1). For this reason, M₀=M_{N}=0 is set to uniquely determine the unknowns. Then, the unknowns Mₖ (k=1, 2, . . . , N−1) are obtained from the equations of the formula 11 so that S(x) is obtained from the formula 8. Thus, each of the signal sequences F(x) and G(x) is interpolated by a spline function.

Although the third-order spline functions are used as one example in the present embodiment, the order may be any order. However, S_{F}(x) and S_{G}(x) preferably have the same order. Further, the sample points and the connection points of the spline functions do not need to correspond to each other one to one as described above. For example, the subinterval [x₀, x₃] from x₀ to x₃ may be represented by one cubic function. Furthermore, points other than the sample points may be set as the connection points. In this case, a manner of setting the connection points is preferably the same between S_{F}(x) and S_{G}(x).

FIG. 5 is a flowchart illustrating an operation example of the spline calculation unit 13. The spline calculation unit 13 calculates the spline functions S_{F}(x) and S_{G}(x) respectively for the signal sequences F(x) and G(x) acquired by the signal acquisition unit 11, in the following procedure.

First, on the basis of the sample points x₀, x₁, . . . , x_{N}, the interval determining unit 12 determines the connection points of the spline functions (step 21). Although the connection points do not need to be identical to the sample points as described above, in this example, for simplicity, the respective sample points are set as the connection points, and the subintervals are determined as [x₀, x₁], . . . , [x_{N-1}, x_{N}]. This interval division is common to F(x) and G(x).

Next, the spline calculation unit 13 solves the formula 11 to obtain M₀, . . . , Mₙ (step 22). At this time, in the formula 11, hₖ=xₖ−xₖ₋₁ is set. In the case of F(x), yₖ=F(xₖ) is set, and in the case of G(x), yₖ=G(xₖ) is set. Then, the spline calculation unit 13 obtains, by the formula 8, a cubic function for one subinterval [xₖ₋₁, xₖ] (step 23). When the next subinterval exists, the process returns to the step 23, and when cubic functions for all of the subintervals [x₀, x₁], . . . , [x_{N-1}, x_{N}] have been obtained, the process advances to step 25 (step 24). To this point, S_{F}(x) is expressed as “the cubic function f₀ in [x₀, x₁], . . . , and the cubic function f_{N-1} in [x_{N-1}, x_{N}]”. S_{G}(x) is also expressed as “the cubic function g₀ in [x₀, x₁], . . . , and the cubic function g_{N-1} in [x_{N-1}, x_{N}]”. Accordingly, the spline calculation unit 13 makes the subintervals and the polynomials related to each other, and stores S_{F}(x) and S_{G}(x) in the function storing unit 14 (step 25). With that, the operation of the spline calculation unit 13 is finished.

Various calculating methods for spline interpolation have been proposed in the past. The spline calculation unit 13 may use a different known calculating method without limitation to the method in FIG. 5.

Next, the process in which the polynomial-sequence calculating unit 15 calculates a polynomial sequence at the step 30 in FIG. 4 will be described. FIG. 6 is a flowchart illustrating an operation example of the polynomial-sequence calculating unit 15 of the first embodiment.

First, for a current processing-target subinterval [xₖ₋₁, xₖ], the polynomial-sequence calculating unit 15 acquires, from the function storing unit 14, the cubic functions fₖ and gₖ of the spline functions S_{F} and S_{G}, and sets the respective obtained functions as ψ₀ and ψ₁ (step 31). Then, a variable j is set as j=1 (step 32). The polynomial-sequence calculating unit 15 determines whether or not the order of ψⱼ is zero. The process advances to step 34 when the order is not zero, whereas the process advances to step 37 described below when the order is zero (step 33).

When the order of ψⱼ is not zero, the polynomial-sequence calculating unit 15 divides ψⱼ₋₁ by ψⱼ (step 34), and the remainder is set as −ψⱼ₊₁ (step 35). Then, one is added to j (step 36), and the process returns to the step 33. When the order of ψⱼ is zero, the polynomial-sequence calculating unit 15 stores the polynomial sequence {ψ₀, . . . , ψⱼ} in the function storing unit 14 (step 37). With that, the operation of the polynomial-sequence calculating unit 15 is finished.

In the process of FIG. 6, a Euclidean algorithm is applied to ψ₀ and ψ₁ (i.e., the cubic functions fₖ and gₖ of the spline functions S_{F} and S_{G}) to obtain the polynomial sequence {ψ₀, . . . , ψⱼ}. However, although the description is omitted in the above, in order to obtain an unwrapped phase from the number of sign changes in the numerical sequence obtained from the polynomial sequence {ψ₀, . . . , ψⱼ}, when each polynomial ψⱼ has the power of x as a factor (i.e., the term of the zeroth order becomes zero), the part made by deleting the power of x is newly defined as ψⱼ to perform the process in FIG. 6. The Euclidean algorithm mentioned in the present embodiment includes such a modified example.

Generally, it is known that when a pair of polynomials (f(x), g(x)) taking real values are given, a polynomial remainder sequence obtained by applying a Euclidean algorithm to them meets a condition called a Sturm sequence. In order to obtain a continuous unwrapped phase from (f(x), g(x)), an appropriate integral multiple of π is added as a correction term to a principal value. Non-patent Literatures 1 and 2 indicate that this correction term can be determined from signs (+, −) of (f(x), g(x)) before and after x where f(x) becomes zero. The method in FIG. 6 enables the correction term to be accurately obtained by using a property of a Sturm sequence, without information on a position of x where f(x) becomes zero.

Thus, the signal processing device 10 of the present embodiment uses the mathematically strict method in a part of determining an unwrapped phase from polynomials. For this reason, when input signal sequences can be well approximated by piecewise polynomials, phase unwrapping can be accurately performed. The input signal sequences are approximated by spline functions so that polynomials each making connection between the sample points can be accurately obtained, leading to improvement in accuracy of phase unwrapping.

### Second Embodiment

The signal processing device 10 of the first embodiment performs the Euclidean algorithm illustrated in FIG. 6 at the time of calculating a polynomial sequence for determining an unwrapped phase. However, in this method, numerical instability may not be avoided when the order of polynomials becomes high. This is because the process in FIG. 6 includes the step (step 34) of division of a polynomial (ψⱼ₊₁(x) is obtained by multiplying, by −1, a remainder in dividing ψⱼ₋₁(x) by ψⱼ(x)). When a computing machine actually tries to perform the process in FIG. 6, there is a possibility that this division of the polynomials is not accurately performed. For example, although the answer in dividing 1 by ⅓ is 3 with a remainder of 0, the computing machine may not express ⅓ accurately, and for this reason, the remainder does not become 0 in fact. In addition, even when denominators and numerators of coefficients are separated from each other to be stored as integers respectively, digits of coefficients of polynomials become excessively large in the course of the Euclidean algorithm, and thus the coefficients may not be accurately stored. Namely, when the Euclidean algorithm is attempted to be implemented straight in a computing machine, a value of a coefficient of some polynomial becomes inaccurate halfway, and a step at which the inaccurate coefficient is used to create a next polynomial is repeated, so that from the middle, coefficients of a polynomial are shifted from actual coefficients. Since accumulation of such an error in numerical calculation possibly influences a calculation result of phase unwrapping, it is desirable to generate a polynomial sequence without directly performing the Euclidean algorithm.

In view of above, according to the signal processing device 10 of the second embodiment, after the spline calculation unit 13 calculates spline functions, the polynomial-sequence calculating unit 15 calculates a polynomial sequence that is an positive constant multiple of a polynomial remainder sequence obtained by the process in FIG. 6. The polynomial sequence is obtained by calculating a subresultant described below. When a pair of polynomials to which a Euclidean algorithm is applied are represented by (f(x), g(x)), all of coefficients of the polynomial obtained by calculating the subresultant are calculated by using addition, subtraction, and multiplication of coefficients of f(x) and g(x). Accordingly, additional creation of a next polynomial from polynomials including inaccurate coefficients as described above does not occur. Since the polynomial-sequence calculating unit 15 of the second embodiment does not directly perform the Euclidean algorithm in FIG. 6, instability in numerical calculation as described above does not occur.

The signal processing device 10 of the second embodiment is the same as the signal processing device 10 of the first embodiment except for process contents performed by the polynomial-sequence calculating unit 15. For this reason, description about a part other than the process contents of the polynomial-sequence calculating unit 15 is omitted.

Prior to the subresultant, first, a resultant is described. A resultant is a determinant of a matrix for determining whether or not an m-th order polynomial f(x)=aₘx^{m}+aₘ₋₁x^{m-1}+ . . . a₀ and an n-th order polynomial g(x)=bₙxⁿ+bₙ₋₁xⁿ⁻¹+ . . . b₀ have a common root, and is a determinant of a (m+n)-th order square matrix such as the formula 12. All of elements that are blank parts in the matrix are zero. In the present embodiment, the matrix of the formula 12 is referred to as “resultant matrix”.

$$\overbrace{( \begin{matrix}{a}_{m} & {a}_{m - 1} & … & {a}_{1} & {a}_{0} & & & \\ & {a}_{m} & {a}_{m - 1} & … & {a}_{1} & {a}_{0} & & \\ & & ⋱ & ⋱ & & ⋱ & ⋱ & \\ & & & {a}_{m} & {a}_{m - 1} & … & {a}_{1} & {a}_{0} \\ {b}_{n} & {b}_{n - 1} & … & {b}_{1} & {b}_{0} & & & \\ & {b}_{n} & {b}_{n - 1} & … & {b}_{1} & {b}_{0} & & \\ & & ⋱ & ⋱ & & ⋱ & ⋱ & \\ & & & {b}_{n} & {b}_{n - 1} & … & {b}_{1} & {b}_{0}\end{matrix} )}^{m + n} \begin{matrix}\} n \\ \} m\end{matrix} \qquad [ Formula 12 ]$$

From the resultant matrix of the formula 12, 2j columns on the right side, j rows on the lower side for coefficients a₀, . . . , aₘ, and j rows on the lower side for coefficients b₀, . . . , bₙ are excluded to make a minor matrix Mⱼ(f, g) such as the formula 13. In this case, p is set as p=min{m, n}, and j is j=0, 1, . . . , p−1.

$$[ Formula 13 ]$$

$${M}_{j} ( f , g ) = \overbrace{( \begin{matrix}{a}_{m} & … & … & {a}_{j} & {a}_{j - 1} & … & {a}_{0} & & & \\ & {a}_{m} & … & … & {a}_{j} & {a}_{j - 1} & … & {a}_{0} & & \\ & & ⋱ & & & ⋱ & ⋱ & & ⋱ & \\ & & & {a}_{m} & … & … & {a}_{j} & {a}_{j - 1} & … & {a}_{0} \\ & & & & ⋱ & & & ⋱ & ⋱ & \\ & & & & & {a}_{m} & … & … & {a}_{j} & {a}_{j - 1} \\ & & & & & & {a}_{m} & … & {a}_{j + 1} & {a}_{j} \\ {b}_{n} & … & … & {b}_{j} & {b}_{j - 1} & … & {b}_{0} & & & \\ & {b}_{n} & … & … & {b}_{j} & {b}_{j - 1} & … & {b}_{0} & & \\ & & ⋱ & & & ⋱ & ⋱ & & ⋱ & \\ & & & {b}_{n} & … & … & {b}_{j} & {b}_{j - 1} & … & {b}_{0} \\ & & & & ⋱ & & & ⋱ & ⋱ & \\ & & & & & {b}_{n} & … & … & {b}_{j} & {b}_{j - 1} \\ & & & & & & {b}_{n} & … & {b}_{j + 1} & {b}_{j}\end{matrix} )}^{m + n - 2 j} \begin{matrix}\begin{matrix} \\ \\ \\ \\ \\ \\ \end{matrix} \} n - j \\ \begin{matrix} \\ \\ \\ \\ \\ \\ \end{matrix} \} m - j\end{matrix}$$

Further, for the matrix Mⱼ(f, g) of the formula 13, elements in the column at the right end are replaced, one by one from the upper side, with f(x)x^{n-j-1}, f(x)x^{n-j-2}, . . . , f(x), g(x)^{m-j-1}, g(x)x^{m-j-2}, . . . , and g(x) to make a matrix Rⱼ(f, g) such as the formula 14. The determinant of this matrix is a j-th order subresultant of f(x) and g(x). Since Rⱼ(f, g) includes polynomials as elements of the matrix, the subresultant that is the determinant thereof becomes a polynomial, as well. In the present embodiment, the matrix of the formula 14 is referred to as “subresultant matrix”.

$$[ Formula 14 ]$$

$${R}_{j} ( f , g ) = \overbrace{( \begin{matrix}{a}_{m} & … & … & {a}_{j} & {a}_{j - 1} & … & {a}_{0} & & & f ( x ) {x}^{n - j - 1} \\ & {a}_{m} & … & … & {a}_{j} & {a}_{j - 1} & … & {a}_{0} & & f ( x ) {x}^{n - j - 2} \\ & & ⋱ & & & ⋱ & ⋱ & & ⋱ & ⋮ \\ & & & {a}_{m} & … & … & {a}_{j} & {a}_{j - 1} & … & f ( x ) {x}^{j} \\ & & & & ⋱ & & & ⋱ & ⋱ & ⋮ \\ & & & & & {a}_{m} & … & … & {a}_{j} & f ( x ) x \\ & & & & & & {a}_{m} & … & {a}_{j + 1} & f ( x ) \\ {b}_{n} & … & … & {b}_{j} & {b}_{j - 1} & … & {b}_{0} & & & g ( x ) {x}^{m - j - 1} \\ & {b}_{n} & … & … & {b}_{j} & {b}_{j - 1} & … & {b}_{0} & & g ( x ) {x}^{m - j - 2} \\ & & ⋱ & & & ⋱ & ⋱ & & ⋱ & ⋮ \\ & & & {b}_{n} & … & … & {b}_{j} & {b}_{j - 1} & … & g ( x ) {x}^{j} \\ & & & & ⋱ & & & ⋱ & ⋱ & ⋮ \\ & & & & & {b}_{n} & … & … & {b}_{j} & g ( x ) x \\ & & & & & & {b}_{n} & … & {b}_{j + 1} & g ( x )\end{matrix} )}^{m + n - 2 j} \begin{matrix}\begin{matrix}\begin{matrix} \\ \end{matrix} \\ \\ \\ \\ \\ \\ \end{matrix} \} n - j \\ \begin{matrix}\begin{matrix} \\ \end{matrix} \\ \\ \\ \\ \\ \\ \end{matrix} \} m - j\end{matrix}$$

It is assumed that both of polynomials f(x) and g(x) in a processing-target subinterval of the spline functions S_{F}(x) and S_{G}(x) calculated by the spline calculation unit 13 are m-th order. For the polynomials f(x) and g(x), Ψ₀(x)=f(x) and Ψ₁(x)=g(x) are set. Then, for j=2, . . . , q, a polynomial sequence {Ψ₀(x), Ψ1(x), . . . , Ψ_{g}(x)} is made by the formula 15. In this regard, q is the number at which Ψ_{q} becomes zeroth order (a constant).

$${Ψ}_{j} ( x ) = {( - 1 )}^{\frac{( j - 1 ) ( j + 2 )}{2}} {b}_{m} det ( {R}_{m - j + 1} ( f ( x ) , g ( x ) ) ) \qquad [ Formula 15 ]$$

In this formula, bₘ is a coefficient of the m-th order term in g(x). For example, when Ψ₀(x) and Ψ₁(x) are the third order, this polynomial sequence becomes a sequence having a finite number of terms in which the order is decreased one by one such that Ψ₂(x) is the second order, Ψ₃(x) is the first order, and Ψ₄(x) is the zeroth order (a constant), for example (in this example, q is q=4, and the relation q=m+1 exists).

Then, the thus-obtained polynomials Ψ₀(x), Ψ₁(x), . . . , and Ψ_{q}(x) become positive constant multiples of the corresponding polynomials ψ₀(x), . . . , and ψ_{q}(x) obtained by the process of FIG. 6. In other words, the relation Ψ₀(x)=c₀ψ₀(x), . . . , Ψ_{q}(x)=c_{q}ψ_{q}(x) is established where c₀, . . . , and c_{q}, are positive constants. Further, when this polynomial sequence {Ψ₀(x), Ψ₁(x), . . . , Ψ_{q}(x)} is obtained, a Euclidean algorithm is not directly performed, so that instability in numerical calculation does not occur.

The signal processing device 10 of the present embodiment obtains an unwrapped phase on the basis of the number of sign changes in a numerical sequence created from a polynomial sequence, and the difference regarding positive constant multiples does not exert an influence at the time of counting the number of sign changes. Accordingly, in the second embodiment, by calculating this polynomial sequence {Ψ₀(x), Ψ₁(x), . . . , Ψ_{q}(x)}, a problem of instability in numerical calculation is avoided, and a continuous unwrapped phase is determined.

In the first embodiment, after a polynomial sequence is calculated, a value is substituted for a variable x to generate a numerical sequence. Meanwhile, in the second embodiment, when a value is substituted for a variable x before calculating a subresultant, det(Rⱼ(f, g)) becomes a determinant of numerical values, and thus the numerical sequence can be directly obtained. Since a determinant of numerical values can be easily calculated, also in terms of a calculation amount, the process of the second embodiment is more simplified than the process of the first embodiment.

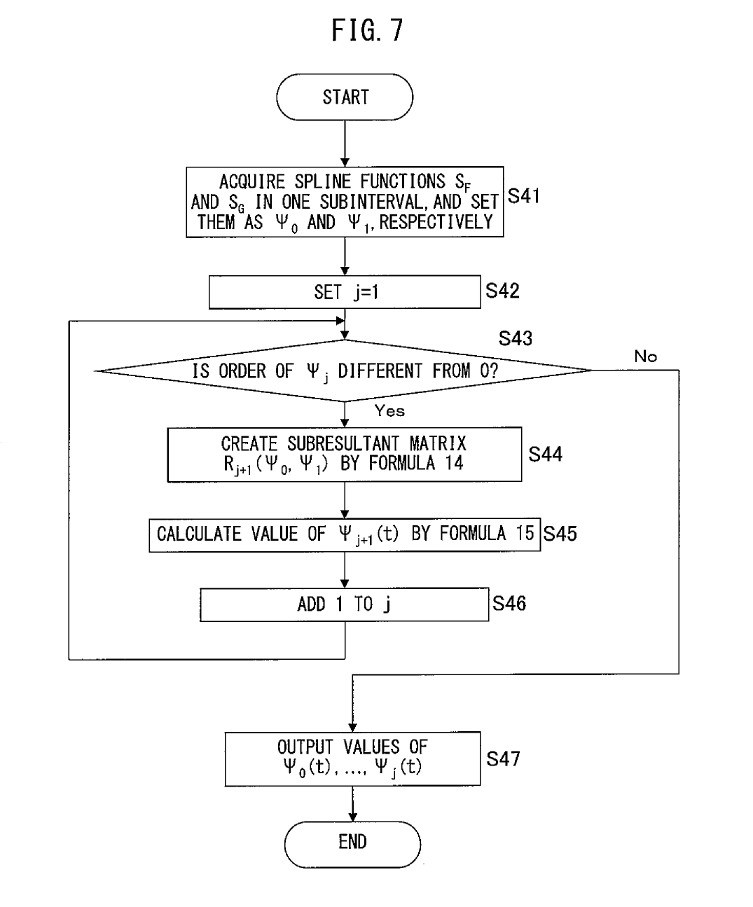

The process in which the polynomial-sequence calculating unit 15 of the second embodiment calculates a polynomial sequence at the step 30 in FIG. 4 is summarized and described below. FIG. 7 is a flowchart illustrating an operation example of the polynomial-sequence calculating unit 15 of the second embodiment.

First, for a current processing-target subinterval [xₖ₋₁, xₖ], the polynomial-sequence calculating unit 15 acquires, from the function storing unit 14, the cubic functions fₖ and gₖ of the spline functions S_{F} and S_{G}, and sets the respective obtained functions as Ψ₀ and Ψ₁ (step 41). Then, a variable j is set as j=1 (step 42). The polynomial-sequence calculating unit 15 determines whether or not the order of Ψⱼ is zero. The process advances to step 44 when the order is not zero, whereas the process advances to step 47 described below when the order is zero (step 43).

When the order of Ψⱼ is not zero, the polynomial-sequence calculating unit 15 creates a subresultant matrix Rⱼ₊₁(Ψ₀, Ψ₁) by the formula 14 (step 44). Then, a value of x=t at which an unwrapped phase is determined is substituted into Ψⱼ₊₁(x) of the formula 15, and thereafter, a determinant Ψⱼ₊₁(t) of numerical values is calculated (step 45). When obtaining an unwrapped phase for another point in the subinterval [xₖ₋₁, xₖ], calculation of a determinant at the step 45 may be repeated. After that, one is added to j (step 46), and the process returns to the step 43. When the order of Ψⱼ is zero, the polynomial-sequence calculating unit 15 outputs the numerical sequence {Ψ₀(t), . . . , Ψⱼ(t))} to be received by the sign counting unit 17 (step 47). With that, the operation of the polynomial-sequence calculating unit 15 is finished.

In the same manner as the first embodiment, when each polynomial Ψⱼ(x) has the power of x as a factor (i.e., the term of the zeroth order is zero), the polynomial-sequence calculating unit 15 may newly define the part made by deleting the power of x as Ψⱼ(x) to calculate a polynomial sequence {Ψ₀(x), Ψ₁(x), . . . , Ψ_{q}(x)}.

Thus, the signal processing device 10 of the present embodiment uses the method of a subresultant at the time of calculating a polynomial sequence for determining an unwrapped phase. In this method, a Euclidean algorithm is not directly performed, so that a polynomial sequence can be calculated in a numerically stable manner. Further, the method of the present embodiment can be stably implemented even when floating-point arithmetic is applied or when multiple-precision integer arithmetic is applied.

<Numerical Simulation>

In the following, numerical simulation of phase unwrapping that uses the signal processing device 10 of the first embodiment will be described. In this numerical simulation, f(x) is f(x)=cos(Θ(x)), g(x) is g(x)=sin(Θ(x)), signals in which Θ(x) is expressed by the following formula 16 are monitored at fixed time intervals, and from the monitored signals, a continuous phase Θ(x) of the original signals f(x) and g(x) is estimated. In this numerical simulation, it is examined whether or not a phase of the formula 16 can be accurately obtained from the monitored signals by the phase unwrapping method of the signal processing device 10 and a different phase unwrapping method.

$$Θ ( x ) = - \frac{5}{5 + {( x - 5 )}^{2}} + \frac{1}{200} {x}^{3} - \frac{1}{20} {x}^{2} + \frac{1}{10} x + \frac{1}{6} + sin ( \frac{π}{2} x ) [ rad / π ] \qquad [ Formula 16 ]$$

In the different method, it is assumed that fluctuation in an unwrapped phase generated at the neighboring sample points stays within ±π, and on the basis of this assumption, a wrapped phase of a sample point is changed by an integral multiple of 2π at a time to obtain a value that is not separated by ±π or more from a value of an unwrapped phase at the directly-preceding sample point, and the obtained value is set as the unwrapped phase of the sample point. In the following, this method is referred to a “comparison method”.

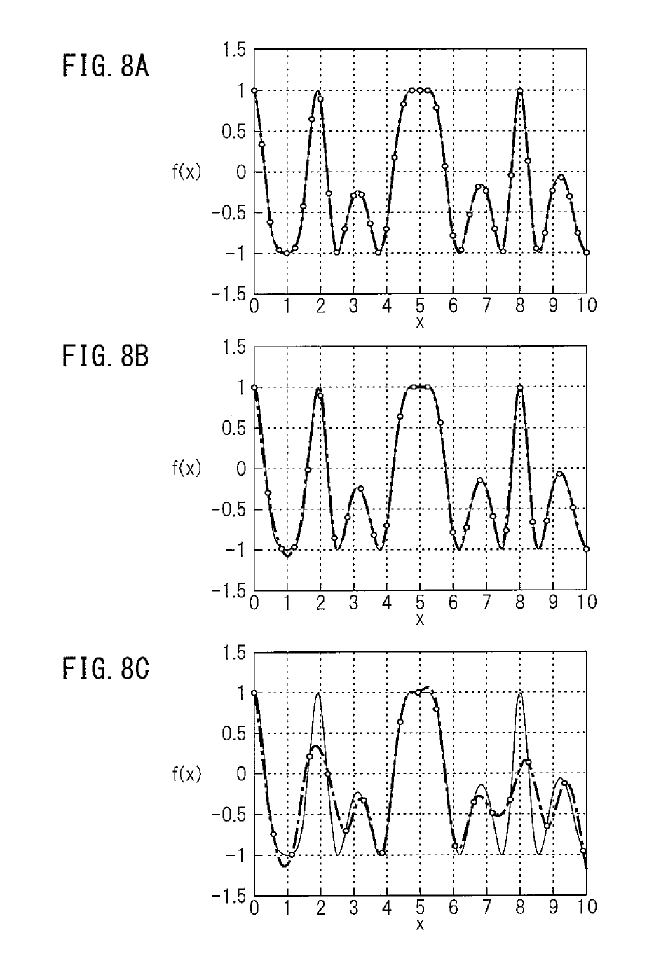

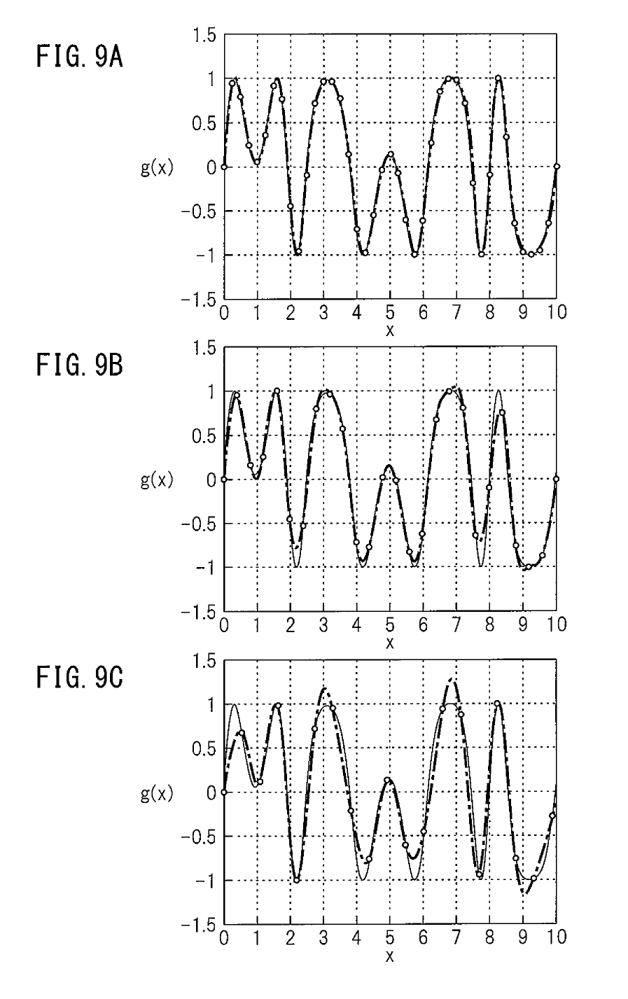

FIGS. 8A to 8C are graphs of the one input signal f(x) used in the numerical simulation of phase unwrapping, and FIGS. 9A to 9C are graphs of the other input signal g(x) used in the numerical simulation. FIGS. 8A to 8C are the graphs when the signal is monitored by setting a sample interval as 0.25, 0.4, and 0.55, respectively. This is common to FIGS. 9A to 12C. In the respective graphs, sample points are indicated by the circles. Further, in the respective graphs, the solid lines are actual f(x) and g(x). The chain lines indicate spline functions calculated by the spline calculation unit 13 on the basis of signal sequences after the signal acquisition unit 11 acquires, as the signal sequences, signals at the respective sample points. In this numerical simulation, each interval between the neighboring sample points is approximated by a cubic function. In FIGS. 8A and 9A in which the sample interval is a small value of 0.25, a difference between the actual f(x) and g(x) and the spline functions is hardly seen, and on the contrary, in FIGS. 8C and 9C in which the sample interval is a large value of 0.55, a difference between both of them is clearly seen.

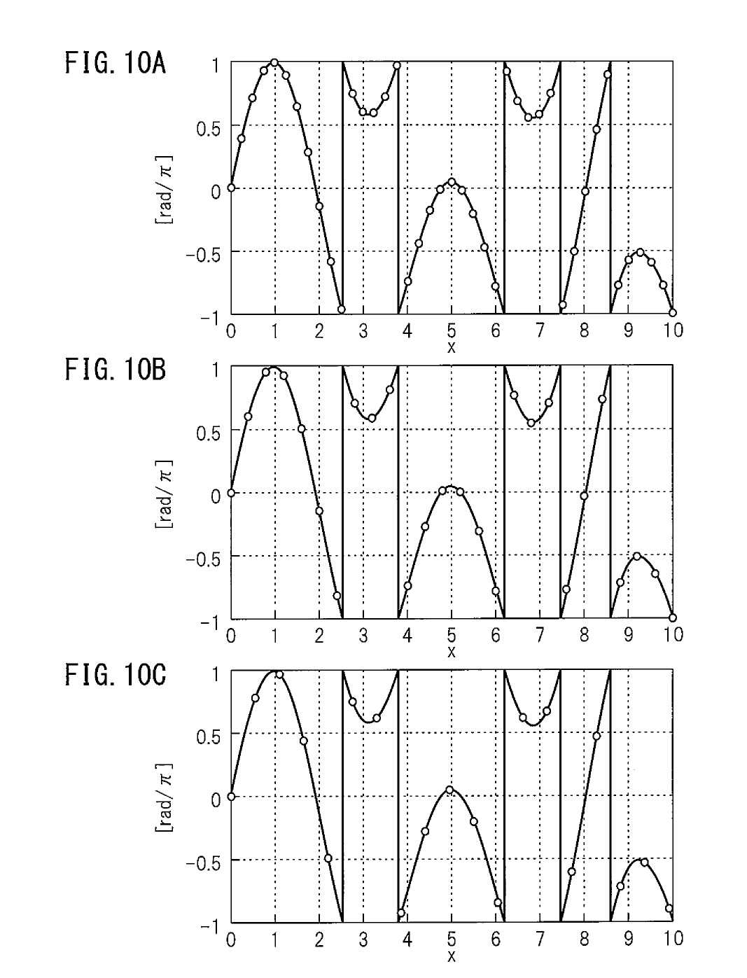

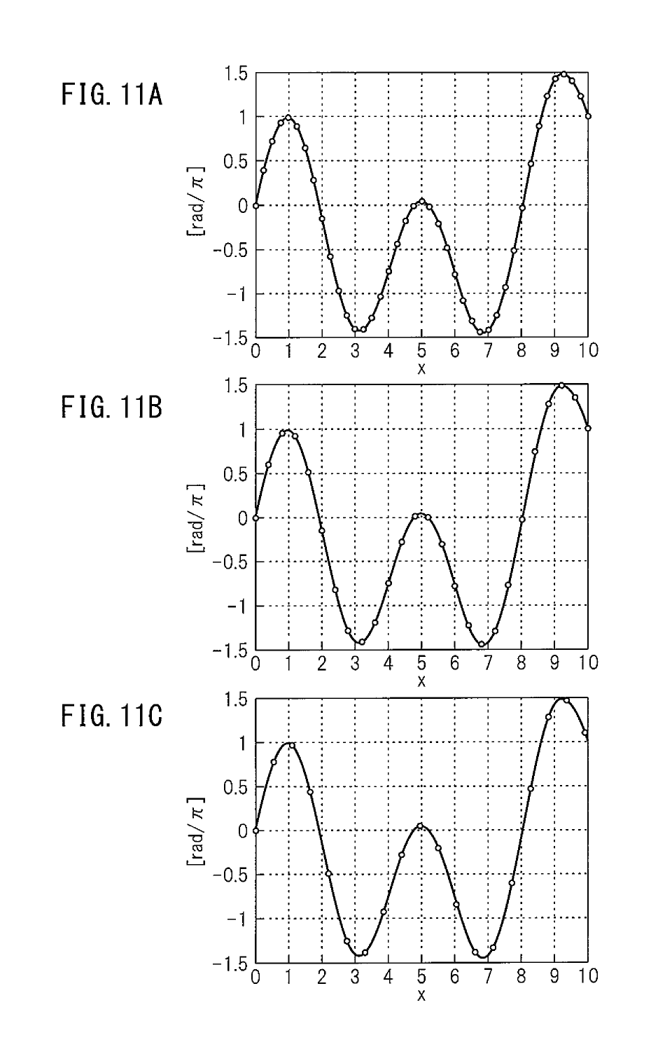

FIGS. 10A to 10C are graphs of a wrapped phase of the input signals of FIGS. 8A to 8C and FIGS. 9A to 9C. FIGS. 11A to 11C are graphs of an unwrapped phase of the input signals of FIGS. 8A to 8C and FIGS. 9A to 9C. The unwrapped phase of FIGS. 11A to 11C is an actual unwrapped phase obtained from the formula 16, and the wrapped phase of FIGS. 10A to 10C is a wrapped phase obtained by limiting a range thereof to (−π, π]. The wrapped phase in FIGS. 10A to 10C is discontinuous at a point where a value thereof changes from π to π or from π to −π, and on the contrary, the unwrapped phase of FIGS. 11A to 11C is a continuous function. Since the graphs of FIGS. 10A to 10C, and the graphs of FIGS. 11A to 11C are formed by plotting the formula 16, all of the graphs are the same regardless of magnitude of the sample interval.

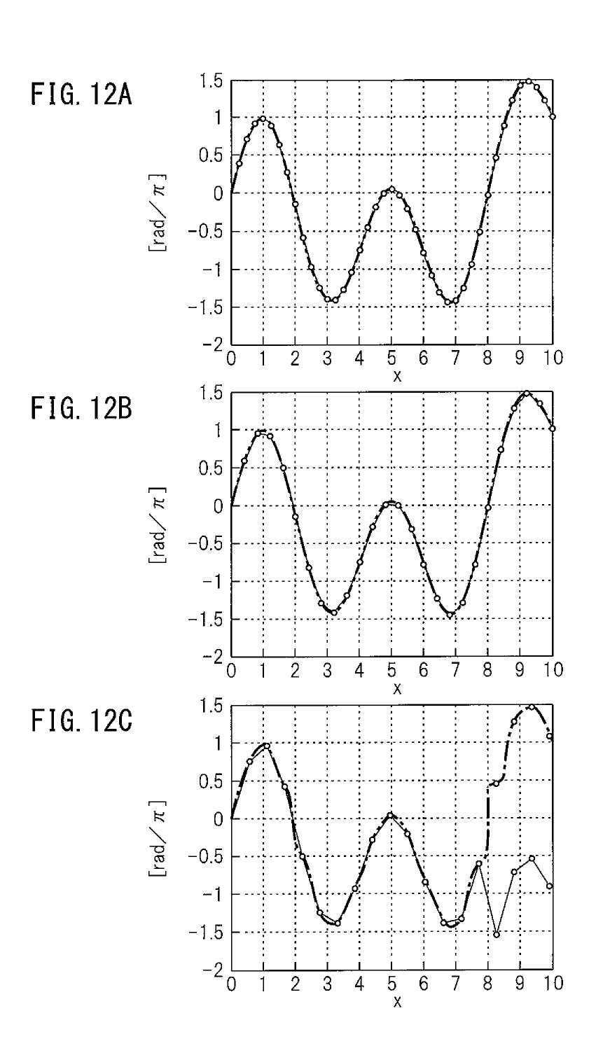

FIGS. 12A to 12C are graphs representing results of the numerical simulation in which phase unwrapping is performed on the input signals of FIGS. 8A to 8C and FIGS. 9A to 9C. The solid lines represent estimated values of Θ(x) obtained by the comparison method, and the chain lines represent estimated values of Θ(x) obtained by the signal processing device 10. In the case of FIGS. 12A and 12B in which the sample intervals are relatively small, the graphs of each of the signal processing device 10 and the comparison method are almost the same as the graphs of FIGS. 11A and 11B. However, in the case of FIG. 12C in which the sample interval is large, a difference from the graph of FIG. 11C can be seen.

In the comparison method, it is assumed that fluctuation in an unwrapped phase generated at the neighboring sample points stays within ±π, and for this reason, when actual unwrapped phases between the neighboring sample points separate by ±π or higher, phase unwrapping may not be performed accurately. This is actually confirmed by FIG. 12C. Referring to FIG. 11C, it can be seen that when the sample interval is 0.55, a difference in the unwrapped phase Θ(x) between x=7.7 and x=8.25 that are neighboring two sample points is larger than π (difference is approximately 1.04π). The solid line in FIG. 12C representing an unwrapped phase obtained by the comparison method is displaced from the curved line in FIG. 11C between the sample points concerned. From this, it is confirmed that in the comparison method, phase unwrapping at x=8.25 fails.

In the signal processing device 10 of the present embodiment, it is confirmed that even in the case of FIG. 12C, an estimated value of an unwrapped phase at each sample point is completely equal to an actual unwrapped phase in FIG. 11C, and phase unwrapping can be performed entirely with accuracy. In other words, even when a difference in an actual unwrapped phase between neighboring sample points is larger than π, phase unwrapping can be performed accurately. For this reason, a phase signal output from the signal processing device 10 may include neighboring sample points between which the phase difference is larger than π, differently from an output result by the comparison method.

From the result of the above-described numerical simulation, it is understood that in the signal processing device 10 of the present embodiment, when intervals between samples of input signal sequences are set as a sufficiently small value, the input signal sequences can be approximated by spline functions with sufficient accuracy, and phase unwrapping succeeds.

Incidentally, the signal processing device 10 of the present embodiment is preferably implemented in a general-purpose computer such as a personal computer (PC). Lastly, a hardware configuration of such a general-purpose computer is described.

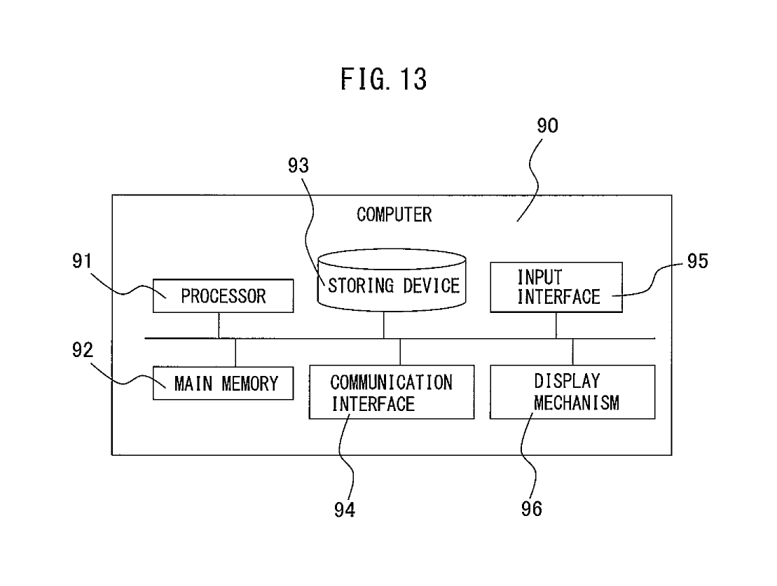

FIG. 13 illustrates a hardware configuration of a computer 90. As illustrated in the drawing, the computer 90 includes a processor 91, a main memory 92, a storing device 93, a communication interface 94, a display mechanism 95, and an input interface 96. The processor 91 executes programs stored in the storing device 93 to implement the above-described respective functions. The main memory 92 stores a program that is being executed by the processor 91, data temporarily used by the program concerned, and the like. The storing device 93 stores the programs to be executed by the processor 91, input-output data concerning these programs, and the like. The communication interface 94 performs data transmission to and data reception from an outside device. The display mechanism 95 includes a video memory, a display, and the like, and displays data and the like to a user. The input interface 96 includes a keyboard, a mouse, and the like, and receives input operation from a user.

The processor 91 illustrated in FIG. 13 reads a program from the storing device 93 into the main memory 92 to execute the program so that each function unit of the signal processing device 10 described above with reference to FIG. 3 is implemented. Further, the function storing unit 14 is implemented by the main memory 92 illustrated in FIG. 13, for example.

The programs implementing the present embodiments may be provided through a communication unit, or may be provided as programs being stored in a recording medium such as a CD-ROM.

### REFERENCE SIGNS LIST

10 signal processing device
11 signal acquisition unit
12 interval determining unit
13 spline calculation unit
14 function storing unit
15 polynomial-sequence calculating unit
16 numerical-sequence generating unit
17 sign counting unit
18 unwrapping processing unit
19 signal outputting unit

1. A signal processing device comprising:
a signal acquisition unit that acquires a pair of signal sequences;
a first calculating unit that calculates a first function and a second function that are piecewise polynomials respectively approximating, by polynomials for each of a plurality of subintervals, the pair of signal sequences acquired by the signal acquisition unit;
a second calculating unit that calculates a numerical sequence of values obtained by substituting one point in each of the plurality of subintervals into a polynomial remainder sequence obtained by applying a Euclidean algorithm to the first function and the second function calculated by the first calculating unit;
a phase determining unit that determines a phase of the pair of signal sequences at the one point, on the basis of a sign of each term of the numerical sequence calculated by the second calculating unit; and
a signal outputting unit that outputs a signal sequence of phases determined by the phase determining unit for each of the plurality of subintervals.

2. The signal processing device according to claim 1, wherein on the basis of the number of changes in signs of values of the numerical sequence between neighboring two terms in the numerical sequence, the phase determining unit determines a value of an indefinite portion of an integral multiple of π that is involved in the phase of the pair of signal sequences at the one point.

3. The signal processing device according to claim 1, wherein for each of the pair of signal sequences, the first calculating unit calculates a piecewise polynomial such that the piecewise polynomial passes through each sample point of the signal sequence concerned, and that polynomials thereof in subintervals neighboring each other are smoothly continued.

4. The signal processing device according to claim 1, wherein instead of the numerical sequence obtained from the polynomial remainder sequence, the second calculating unit calculates a numerical sequence obtained by multiplying, by a positive constant value, respective terms of the numerical sequence concerned, in each of the plurality of subintervals, on the basis of determinants of a plurality of subresultant matrices that are minor matrices of a resultant matrix concerning the first function and the second function.

5. The signal processing device according to claim 1, wherein the signal outputting unit outputs the signal sequence of phases at points for which the phase determining unit has determined the phases, and the points include neighboring two points at which phase difference is larger than π.

6. A signal processing method comprising the steps of:
acquiring a pair of signal sequences;
calculating a first function and a second function that are piecewise polynomials respectively approximating, by polynomials for each of a plurality of subintervals, the acquired pair of signal sequences;
calculating a numerical sequence of values obtained by substituting one point in each of the plurality of subintervals into a polynomial remainder sequence obtained by applying a Euclidean algorithm to the calculated first and second functions;
determining a phase of the pair of signal sequences at the one point, on the basis of a sign of each term of the calculated numerical sequence; and
outputting a signal sequence of phases determined for each of the plurality of subintervals.

7. A non-transitory computer-readable recording medium having recorded thereon a program causing a computer to execute a process, the process comprising:
acquiring a pair of signal sequences;
calculating a first function and a second function that are piecewise polynomials respectively approximating, by polynomials for each of a plurality of subintervals, the acquired pair of signal sequences;
calculating a numerical sequence of values obtained by substituting one point in each of the plurality of subintervals into a polynomial remainder sequence obtained by applying a Euclidean algorithm to the calculated first and second functions;
determining a phase of the pair of signal sequences at the one point, on the basis of a sign of each term of the calculated numerical sequence; and
outputting a signal sequence of phases determined for each of the plurality of subintervals.
